(19) United States
(12) Patent Application Publication
(10) Pub. No.: US 2025/0357315 A1
(43) Pub. Date: Nov. 20, 2025

(54) ZERO TRACK SKIP WITH IN-LINE VIA TO METAL LINE CONNECTION

(71) Applicant: INTERNATIONAL BUSINESS MACHINES CORPORATION, Armonk, NY (US)

(72) Inventors: Nicholas Anthony Lanzillo, Wynantskill, NY (US); Albert Manhee Chu, Nashua, NH (US); Ruilong Xie, Niskayuna, NY (US); Reinaldo Vega, Mahopac, NY (US); Lawrence Alfred Clevenger, Saratoga Springs, NY (US); Brent Alan Anderson, Jericho, VT (US)

(21) Appl. No.: 18/664,889

(22) Filed: May 15, 2024

(51) Int. Cl. H01L 23/522; H01L 21/768; H01L 23/528

(52) U.S. Cl. CPC H01L 23/5226; H01L 21/76816; H01L 21/76877; H01L 23/528

(57) ABSTRACT

A semiconductor device includes a metal line having a longitudinal break therein to provide a first portion and a second portion. A first extended via contacts an end of the first portion at a sidewall of the first extended via. A second extended via is offset from the first extended via and contacts an end of the second portion at a sidewall of the second extended via. The first extended via and the second extended via define a space therebetween, and a zero track skip is disposed within the space.

### BACKGROUND

The present invention generally relates to semiconductor devices and processing methods, and more particularly to zero track skips.

Semiconductor devices include metal structures that can have a number of parallel metal lines connected to metal lines in other layers using vias. In some instances, it is beneficial to have metal lines terminate or be separated along their length. This break in a metal line forms two collinear metal lines of lesser length. A gap between these metal lines is filled with a dielectric material. The dielectric material, called a zero track skip, is defined and bounded by the adjacent metal lines.

The two collinear metal lines of lesser length can be connected to vias in underlying layers. These vias can connect to each of the adjacent ends of the two collinear metal lines of lesser length. A space between these vias can be referred to as a tip-to-tip spacing. In conventional devices where metal lines include a zero track skip, a tip-to-tip spacing can be extremely tight between these vias, especially given ever decreasing node sizes. This means that sufficient space needed to prevent shorting is close to unacceptable margins.

The zero track skip needs to provide sufficient isolation between ends of metal lines and fit within a tip-to-tip spacing of the underlying vias. In addition, the metal lines need to make reliable connections with the vias in this narrow region.

### SUMMARY

In accordance with an embodiment of the present invention, a semiconductor device includes a metal line having a longitudinal break therein to provide a first portion and a second portion. A first extended via contacts an end of the first portion at a sidewall of the first extended via. A second extended via is offset from the first extended via and contacts an end of the second portion at a sidewall of the second extended via. The first extended via and the second extended via define a space therebetween, and a zero track skip is disposed within the space.

In other embodiments, the metal line can include a thickness and the first extended via can include a height that extends through a portion of the thickness. The first extended via can include a height that traverses two metal levels. The second extended via can include a height that traverses two metal levels. The zero track skip can be laterally bounded within the space between the first extended via and the second extended via. The first extended via and the second extended via can have a same height.

In accordance with another embodiment of the present invention, a semiconductor device, includes a pair of subtractively etched extended vias and a dielectric layer disposed on the pair of subtractively etched extended vias. The pair of subtractively etched extended vias have top portions that extend above the dielectric layer. A first metal line portion is connected to a sidewall of one of the pair of subtractively etched extended vias. A second metal line portion is connected to a sidewall of another of the pair of subtractively etched extended vias. The top portions define a space therebetween, and a zero track skip is disposed within the space.

In other embodiments, the first metal line portion and the second metal line portion can include a thickness, and the pair of subtractively etched extended vias can include a height that extends through a portion of the thickness. The pair of subtractively etched extended vias can include a height that traverses two metal levels. The pair of subtractively etched extended vias can include different heights. The zero track skip can be laterally bounded within the space.

In accordance with another embodiment of the present invention, a semiconductor device, includes a metal line having an end portion on a metal level, and an extended via traversing a plurality of metal levels and being embedded in the end portion of the metal line on the metal level such that lateral portions of a top portion of the extended via are connected to the metal line.

In other embodiments, the metal line can include a thickness, and the extended via can include a height that extends through the thickness in its entirety. The metal line can include a thickness, and the extended via can include a height that extends through a portion of the thickness. The extended via can include a height that traverses two metal levels. The extended via can include portions of the metal line on opposite sides of the extended via.

In accordance with another embodiment of the present invention, a method for forming a semiconductor device includes subtractively etching a metal layer to form extended vias; forming a first dielectric layer over the extended vias wherein the extended vias extend above the first dielectric layer; forming a second dielectric layer on the first dielectric layer and over the extended vias to fill a space between top portions of the extended vias to form a zero track skip; removing the second dielectric layer except the zero track skip; and forming a metal line in contact with the extended vias, the metal line being separated by the zero track skip.

In other embodiments, forming the second dielectric layer can include forming a width-dependent dielectric to cover the first dielectric layer without filling the space between top portions of the extended vias; and forming a narrow gap fill dielectric to fill the space between top portions of the extended vias. Removing the second dielectric layer except the zero track skip can include forming a block mask over the zero track skip to prevent removal. Forming the metal line in contact with the extended vias can include forming the metal line with a thickness and the extended vias include a height that extends through a portion of the thickness. The zero track skip and the second dielectric layer can include different materials. Subtractively etching the metal layer can include subtractively etching the metal layer to form vias having at least two different heights.

In accordance with another embodiment of the present invention, a method for forming a semiconductor device includes subtractively etching a metal layer to form extended vias; forming a first dielectric layer over the extended vias wherein the extended vias extend above the first dielectric layer; blanket depositing a metal layer in contact with top portions of the extended vias; forming metal lines having the top portions of the extended vias integrated within the metal lines; performing a metal cut to cut metal lines by opening a space between the extended vias; and forming a dielectric fill in the space between top portions of the extended vias to form a zero track skip.

In other embodiments, forming the metal lines can include forming the metal lines with a thickness and the extended vias include a height that extends through a portion of the thickness. Subtractively etching the metal layer can include subtractively etching the metal layer to form vias having at least two different heights.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a substrate and a metal layer formed thereon after subtractive etching to form subtractive metal features, including metal lines and vias, and after depositing a dielectric material, in accordance with an embodiment of the present invention;

FIG. 2 shows a cross-sectional view after recessing the dielectric material over the subtractive metal features, to expose top portions of extended vias, in accordance with an embodiment of the present invention;

FIG. 3 shows a cross-sectional view after forming a width dependent dielectric layer over the dielectric material and the top portions of the extended vias, which cannot fill a space between the extended vias, in accordance with an embodiment of the present invention;

FIG. 4 shows a cross-sectional view after forming another dielectric layer that fills the space between the extended vias to form a zero track skip, in accordance with an embodiment of the present invention;

FIG. 5 shows a cross-sectional view after removing the width dependent dielectric layer, in accordance with an embodiment of the present invention;

FIG. 6 shows a cross-sectional view after forming metal lines separated by the zero track skip, in accordance with an embodiment of the present invention;

FIG. 7 shows a cross-sectional view after forming a dielectric layer over the dielectric material and the top portions of the extended vias, which fills a space between the extended vias, in accordance with an embodiment of the present invention;

FIG. 8 shows a cross-sectional view after forming a block mask to preserve dielectric material formed in a space between the extended vias, in accordance with an embodiment of the present invention;

FIG. 9 shows a cross-sectional view after blanket depositing a metal layer over the dielectric material and the extended vias, in accordance with an embodiment of the present invention;

FIG. 10 shows a cross-sectional view after patterning metal lines separated by a zero track skip formed in the space between the extended vias, in accordance with an embodiment of the present invention;

FIG. 11 shows a cross-sectional view after blanket depositing a metal layer over the dielectric material and extended vias, in accordance with an embodiment of the present invention;

FIG. 12 shows a cross-sectional view after patterning metal lines which integrate the extended vias therein, in accordance with an embodiment of the present invention;

FIG. 13 shows a cross-sectional view after a metal cut to form a space between metal lines which integrate the extended vias, in accordance with an embodiment of the present invention;

FIG. 14 shows a cross-sectional view after a zero track skip is formed in the metal cut in the space between the extended vias, in accordance with an embodiment of the present invention;

FIG. 15 shows a cross-sectional view of a substrate and a metal layer formed thereon after subtractive etching to form subtractive metal features, including metal lines and vias, and after depositing a dielectric material, in accordance with an embodiment of the present invention;

FIG. 16 shows a cross-sectional view after recessing the dielectric material over the subtractive metal features, to expose a top portion of an extended via, in accordance with an embodiment of the present invention;

FIG. 17 shows a cross-sectional view after blanket depositing a metal layer over the dielectric material and extended via, in accordance with an embodiment of the present invention;

FIG. 18 shows a cross-sectional view after patterning metal lines which integrate the extended via therein and include a portion that extends beyond the extended via, in accordance with an embodiment of the present invention; and

FIG. 19 shows a cross-sectional view after forming a dielectric layer to fill in regions of the metal level, in accordance with an embodiment of the present invention.

### DETAILED DESCRIPTION

In accordance with embodiments of the present invention, devices and methods are described which include zero track skips that are disposed between subtractive vias which extend through a plurality of layers. A zero track skip is provided that can be reliably be formed and can provide sufficient dielectric spacing while making connections between vias and metal lines. Subtractively etched vias can be formed by etching a metal layer or plate. The vias can be formed with underlying metal lines and can extend into a next metal line layer. Metal lines of the next metal layer are formed on and over the vias to form in-line sidewall connections between the vias and the metal lines. The vias extending into the next metal layer define a zero track skip as opposed to the metal lines defining the zero track skip. Metal lines that are formed over the vias are formed to make full contact between a sidewall of the via and an end of the metal line.

In an embodiment, a semiconductor device includes a metal line having a longitudinal break therein to provide a first portion and a second portion. A first extended via contacts an end of the first portion at a sidewall of the first extended via, and a second extended via is offset from the first extended via and contacts an end of the second portion at a sidewall of the second extended via. The first extended via and the second extended via define a space therebetween, and a zero track skip is disposed within the space.

In an embodiment, metal lines and vias for a first metal layer are formed contemporaneously by a subtractive etch process. The vias impinge on a next metal layer. Portions of the vias that extend above a first dielectric layer are employed to form a zero track skip. A second dielectric layer is deposited over the first dielectric layer and over the vias. The second dielectric layer is formed from a material that due to its composition cannot fill a gap between the vias as the vias are close enough to one another to pinch off any dielectric that would otherwise fill the gap. The second dielectric layer relies on a width dependent dielectric gap fill. A third dielectric layer is deposited on the second dielectric layer and is capable of filling the gap. The second dielectric layer is selectively removed leaving the third dielectric layer between the vias to form the zero track skip. A metal deposition is performed and patterned to form metal lines connected to the vias and separated by the zero track skip.

In another embodiment, metal lines and vias for a first metal layer are formed contemporaneously by a subtractive etch process. The vias impinge on a next metal layer. Portions of the vias that extend above a first dielectric layer are employed to form the zero track skip. A second dielectric layer is deposited over the first dielectric layer and over the vias. A block mask is formed over a gap between the vias to preserve the second dielectric layer in the gap as other portions of the second dielectric layer are removed by etching. The block mask is removed and a metal deposition is performed and patterned to form metal lines connected to the vias and separated by the zero track skip.

In yet another embodiment, metal lines and vias for a first metal layer are formed contemporaneously by a subtractive etch process. The vias impinge on a next metal layer. Portions of the vias that extend above a first dielectric layer are employed to form the zero track skip. A blanket metal deposition is performed over the first dielectric layer and over the vias. The blanket metal deposition is patterned to form metal lines. Another patterning forms a metal cut between collinear metal lines. A second dielectric layer is deposited to backfill the metal cut between the metal lines connected to the vias and to form the zero track skip.

In still another embodiment, metal lines and vias for a first metal layer are formed contemporaneously by a subtractive etch process. A via has a height the impinges on a next metal layer. The next metal layer is patterned to include the via. Other portions of the metal line can be removed and filled with a dielectric material. In this way, the via includes a full connection about its surface through an entire thickens of the metal layer formed on the via. In this instance, the zero track skip can have a longer length or provide a connection to one via on one end of a metal line.

In some embodiments, subtractive vias can include a plurality of different types and heights. A first via type can have a first height and a second via type can have a second height which is taller than the first height. The first via type can contact a bottom of a metal line while the second via type extends into a metal line on a same level. For example, the second via type contacts a sidewall of the metal line above it at a metal line end.

In other embodiments, two vias of the second type can be formed adjacent to one another. A tip-to-tip gap or space is defined as the space between the two vias of the second via type formed above adjacent metal lines. The second via type can extend all or part of the way up the height of the metal line above. A dielectric material in the tip-to-tip region of the second via type can be different than a dielectric surrounding the second via types in other regions.

Embodiments in accordance with the present invention enable a zero track skip that can provide full contact between a via sidewall and a metal line end. This provides a resistance benefit by reducing electrical resistance between vias and metal lines.

In accordance with embodiments of the present invention, methods for forming a semiconductor device can include depositing a metal layer. Subtractively etching the metal layer to form vias and metal lines. The vias can include regular vias, metal lines and extended vias. The extended vias are taller than the regular vias, which are taller than the metal lines. The extended vias traverse the via level and a first metal layer and further exceed the first metal layer and the via level in height. A dielectric layer or material is formed over the subtractively etched metal layer (e.g., the regular vias, metal line layer and extended vias). The dielectric layer is recessed to expose a top portion of the extended via (but not the regular vias).

The extended vias are employed to define a gap. The gap is filled with a dielectric material to provide a zero track skip. The zero track skip can be formed using a width dependent dielectric deposition followed by a dielectric deposition that fills the gap. In another method, the gap is filled first and then blocked to preserve the dielectric in the gap. In another embodiment, a metal cut is patterned and then filled to form the zero track skip. The extended vias can enable a zero track skip. This means that the extended vias consume no extra area in the metal layer with which it belongs.

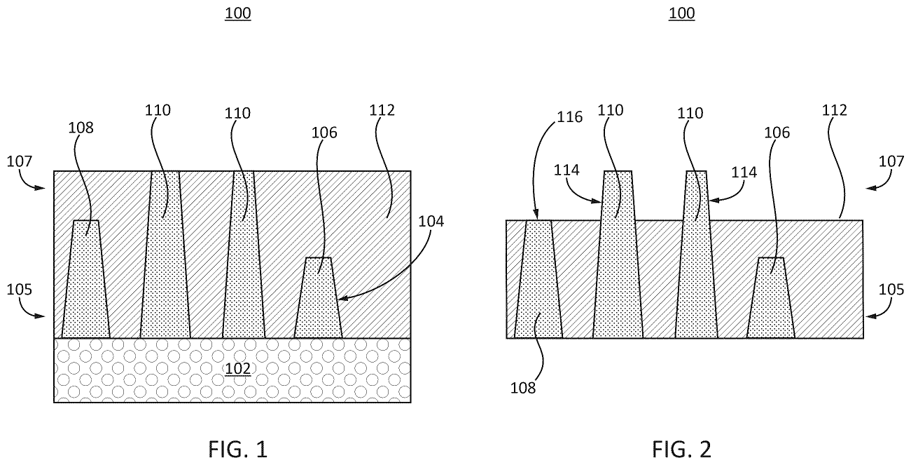

Referring now to the drawings in which like-numerals represent the same or similar elements and initially to FIG. 1, devices and methods for manufacturing a semiconductor device are shown in accordance with embodiments of the present invention. A wafer 100 includes a substrate 102 having one or more layers on which the semiconductor device will be fabricated. FIG. 1 depicts a cross-sectional view of the substrate 102 and a deposited metal layer 104.

The substrate 102 can include any suitable structure and can include a semiconductor substrate, e.g., a bulk semiconductor, a semiconductor-on-insulator (SOI) substrate, etc., and preferably includes a monocrystalline semiconductor. The substrate 102 can include a fabricated front end of line (FEOL) structure having field effect transistors, and other devices formed thereon. In addition, the substrate 102 can include middle of the line (MOL) contacts to connect the FEOL structures to back end of line (BEOL) metal structures through dielectric materials.

In one example, the substrate 102 can include a Si-containing semiconductor substrate. Illustrative examples of Si-containing semiconductor materials suitable for the semiconductor substrate can include, but are not limited to, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

The substrate 102 can be fabricated through the formation of MOL structures. However, it should be understood that the structures described herein can be included in any metallization for any device type. The metallization described herein can be included in BEOL structures, backside interconnect layers, far back end of the line (FBEOL) structures or any other structures having a plurality of metal line layers and at any position where skip vias can be employed.

A conductive deposition is performed over the substrate 102 to form a metal layer 104. The metal layer 104 can include, e.g., Cu, Ru, Mo, Rh, W, Ir, and alloys or combinations of these and other conductive materials. In a particularly useful embodiment, the conductive deposition includes Ru. The conductive deposition can be formed using a deposition method, such as, e.g., chemical vapor deposition (CVD), plasma enhanced CVD (PECVD), atomic layer deposition (ALD) or any other suitable deposition method. The conductive deposition can optionally be planarized, e.g., by chemical mechanical polishing (CMP).

A subtractive etch process or processes are carried out to form different metal structures from the metal layer 104. In an embodiment, metal lines 106 are formed by a first etch process by exposing portions of the metal layer 104 through an etch mask (not shown). Then, another etch mask (not shown) can be employed to etch vias 108 while blocking off other regions of the wafer 100. The vias 108 extend further than the metal lines 106 (e.g., are taller). Another etch mask (not shown) can be employed to etch extended vias 110 while blocking off other regions of the wafer 100. The extended vias 110 extend further than the metal lines 106 and the vias 108 (regular vias). Each of the features of the subtractive etch can be formed in any order since their formation is independently carried out relative to the others.

The vias 108 and metal lines 106 occupy a metal level, which can be referred to as a first metal level 105 (e.g., M1 metal). It should be understood metal level 105 can be anywhere in a stack of metal levels and is not limited to being positioned in a first metal level position. The extended via 110 extends beyond the first metal level 105 to at least partially traverse a second metal level 107.

It should be understood that three sizes of metal structures are illustratively depicted in FIG. 1. However, some embodiments can include one, two, three or more metal structures of differing height and/or widths as needed in accordance with a particular embodiment.

A dielectric material 112 is formed on the wafer 100. The dielectric material 112 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric material 112 can be deposited using CVD, although other deposition methods can be employed.

The dielectric material 112 can be planarized to expose a top surface of the extended via 110. The planarization process can include a chemical mechanical polishing (CMP) process.

Referring to FIG. 2, the dielectric material 112 is recessed to expose a top portion 114 of the extended vias 110. The recess process can include a wet or dry etch that recesses the dielectric material 112 until a top 116 of the via 108 is reached.

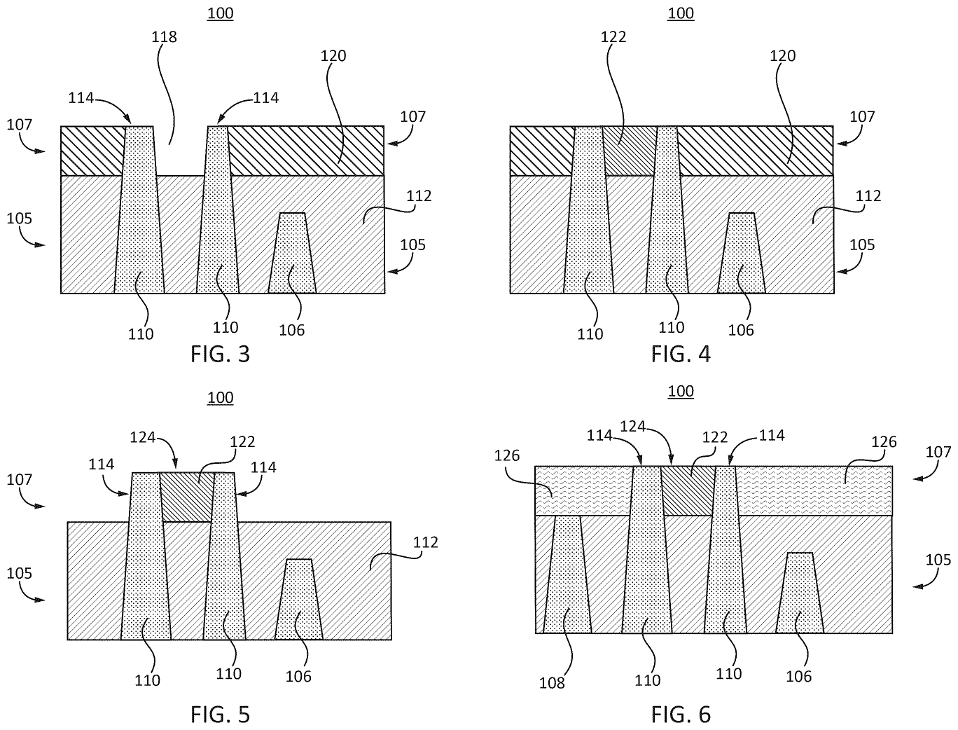

Referring to FIG. 3, a dielectric deposition is performed that covers the surface of the dielectric material 112 and a top and sides of the top portions 114 of the extended vias 110. The dielectric deposition can include a nitride or oxynitride (e.g., SiN, SiON, etc.). Other dielectric materials can also be employed.

In most cases, it is important that a dielectric material completely fill features. However, in accordance with an embodiment of the present invention, a gap 118 is not filled during formation of a dielectric layer 120. The dielectric layer 120 can be deposited using a chemical vapor deposition (CVD) or a spin-on process. Each of these processes can be adjusted to prevent filling very narrow gaps such as the gap 118. A plasma enhanced chemical vapor deposition (PECVD) process can be employed to provide a lower deposition rate inside the gap 118 than at other locations on a surface of the wafer 100. The differential deposition rates can create structures overhanging the gap 118 leading to a void within the gap 118. Phosphosilicate glass (PSG) and borophosphosilicate glass (BPSG) are usually deposited using atmospheric pressure CVD (APCVD), sub-atmospheric pressure CVD (SACVD) or low pressure CVD (LPCVD). Depending on the process conditions and precursors, these materials and methods can be employed to avoid filling narrow gaps especially at lower temperatures e.g., about 800° C. or less. The inclusion of phosphorous and boron in the glass lowers the glass transition and flow temperatures. After deposition of the dielectric layer 120, the gap 118 remains between the extended vias 110.

Referring to FIG. 4, another dielectric deposition can be performed using any suitable process capable of narrow gap filling. Chemical vapor deposition (CVD), atomic layer deposition (ALD) or other deposition techniques can be employed to deposit dielectric materials to fill the gap 118. Note that that material used for dielectric layer 120 can be selectively removed relative to the dielectric material of dielectric layer 122. A planarization process, such as chemical mechanical polishing (CMP) can be performed to remove excess material from the free surface of the wafer 100.

Referring to FIG. 5, an etch is performed to remove the dielectric layer 120 from surfaces of the dielectric material 112 and to expose the top portions 114 of the extended vias 110. The etch does not remove the dielectric layer 122 from in between the top portions 114 of the extended vias 110. The material of the dielectric layer 122 forms a zero track skip 124. The zero track skip 124 will provide isolation between extended vias 110 in line of a metal line to be formed. A height of the extended via 110 will correspond with a thickness of a metal line of a next metal level 107.

Referring to FIG. 6, a blanket deposition is performed over the zero track skip 124 and the top portions 114 of the extended vias 110. The blanket deposition is patterned to form a metal line 126 (or line) at the second metal level 107. The metal line 126 can include, e.g., Cu, Ru, Mo, Rh, W, Ir, and alloys or combinations of these and other conductive materials. In a particularly useful embodiment, the conductive material includes Cu. The conductive material can be formed using a deposition method, such as, e.g., CVD, plasma enhanced CVD (PECVD), ALD or any other suitable deposition method. The conductive material can be planarized, e.g., by CMP. CMP exposes a top surface of the top portions 114 of the extended vias 110. The height of the metal line 126 corresponds with a height of the extended vias 110. This ensures reliable electrical isolation in-line across portions of the metal line 126.

The zero track skip 124 acts as a break between portions of the metal line 126. Boundaries of the zero track skip 124 are defined by the extended vias 110, which extend from a different metal level 105 than the metal level 107 where the zero track skip 124 is located. In addition, the extended vias 110 are connected to the portions of the metal line 126 at interfaces 128 which extend along an entire sidewall of the extended vias 110 (along the top portions 114 of the extended vias 110). This improves resistance properties between the extended vias 110 and the portions of the metal line 126. Since the metal line 126 can be made thicker, resistance properties can be improved further by increasing contact surface area between the extended vias 110 and the portions of the metal line 126 as a result of increasing a height of the metal line 126. Processing can continue with the formation of additional components, which can include additional dielectric layers and metal structures.

In this and the other embodiments described herein, a thickness of the metal line 126 can be greater than the extended via 110. This means that a height of the via 110 can extend through a portion of the thickness of the metal line 126 or through the thickness of the metal line in its entirety. The extended via 110 can include a height that traverses two or more metal levels. The extended vias 110 can have a same height or different heights within the metal line 126.

In this and the other embodiments described herein, the metal line 126 or portions thereof can connect with a top of one or more regular vias 108. In this way, additional connections can be made, as needed.

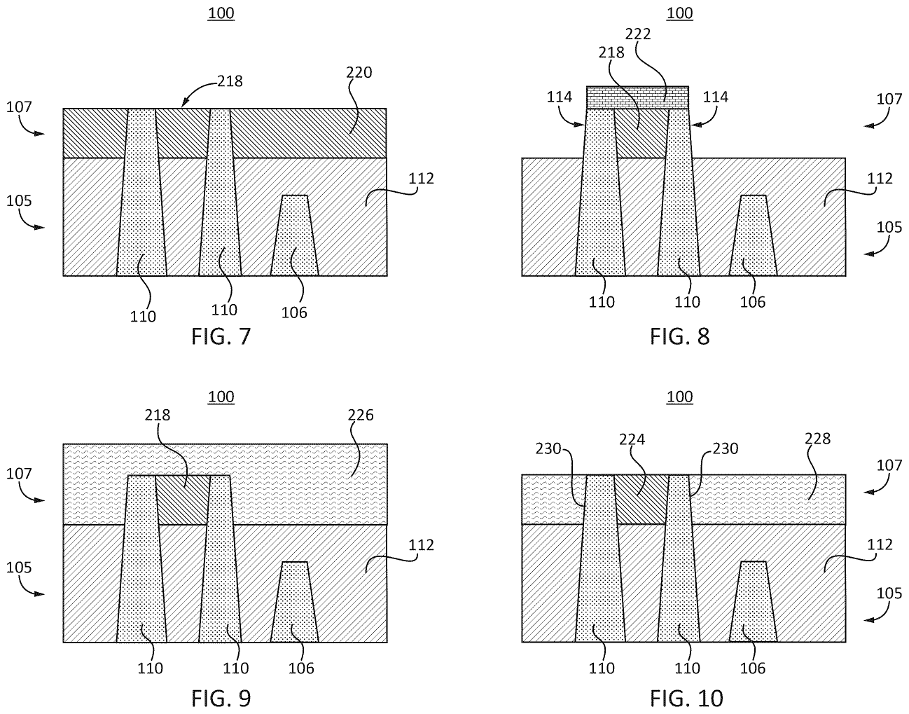

Referring to FIG. 7, beginning with the structure of FIG. 2, a dielectric material 220 is formed on the wafer 100 and covers the dielectric material 112 and the extended vias 110. The dielectric material 220 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric material 220 includes a material that can be selectively removed relative to the dielectric material 112. The dielectric material 220 can be deposited using CVD, although other deposition methods can be employed. The dielectric material 220 includes a portion 218 that fills a region in between the extended vias 110. The portion 218 with form a zero track skip as will be described. The dielectric material 220 can be planarized, e.g., by CMP.

Referring to FIG. 8, a block mask 222 is formed and patterned over the portion 218 to protect the material of the portion 218 during the removal of other portions of the dielectric material 220. The block mask 222 can include a patterned photoresist or other etch mask or masks that can be applied to a surface of the dielectric material 220 and etched or developed to form the block mask 222 over the portion 218. An etch process is performed to remove the dielectric material 220 except the portion 218 which is protected by the block mask 222. The etch process can include any suitable etch process that can selectively remove the dielectric material 220 relative to the dielectric material 112, the extended vias 110 and the block mask 222. The block mask 222 (or masks) can then be removed by a selective etch or polish process to expose the portion 218.

Referring to FIG. 9, a conductive deposition (blanket deposition) process can be performed to form a metal layer 226. The metal layer 226 can include materials, such as, e.g., Cu, Ru, Mo, Rh, W, Ir, and alloys or combinations of these and other conductive materials. In a particularly useful embodiment, the metal layer 226 includes Cu. The metal layer 226 can be formed using a deposition method, such as, e.g., CVD, PECVD, ALD or any other suitable deposition method. The metal layer 226 covers exposed portions of the extended vias 110.

Referring to FIG. 10, the metal layer 226 is etched to pattern metal lines 228. A planarization process (e.g., CMP) is employed to remove material to expose the portion 218, which forms a zero track skip 224.

The zero track skip 224 acts as a break between portions of the metal line 228. The boundaries of the zero track skip 224 are defined by the extended vias 110, which extend from a different metal level 105 than the metal level 107 where the zero track skip 224 is located. In addition, the extended vias 110 are connected to the portions of the metal line 228 at interfaces 230 which extend along an entire sidewall of the extended vias 110. This improves resistance properties between the extended vias 110 and the portions of the metal line 228. Since the metal line 228 can be made thicker, resistance properties can be improved further by increasing contact surface area between the extended vias 110 and the portions of the metal line 228 by increasing a height of the metal line 228. Processing can continue with the formation of additional components, which can include additional dielectric layers and metal structures.

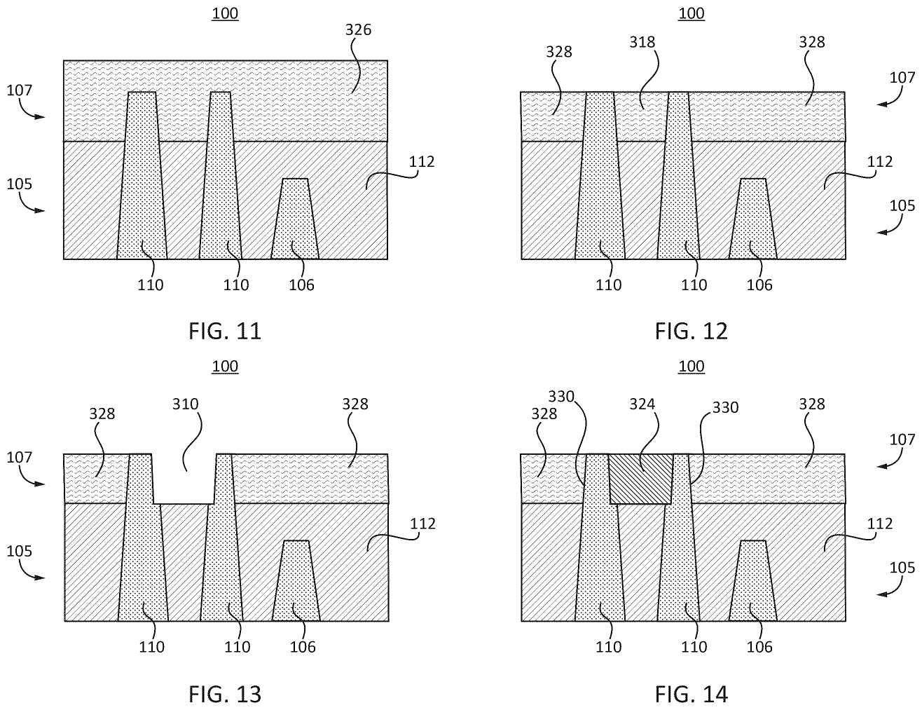

Referring to FIG. 11, beginning with the structure of FIG. 2, a conductive deposition (blanket deposition) process can be performed to form a metal layer 326. The metal layer 326 can include materials, such as, e.g., Cu, Ru, Mo, Rh, W, Ir, and alloys or combinations of these and other conductive materials. In a particularly useful embodiment, the metal layer 326 includes Ru. The metal layer 326 can be formed using a deposition method, such as, e.g., CVD, PECVD, ALD or any other suitable deposition method. The metal layer 326 covers exposed portions of the extended vias 110.

Referring to FIG. 12, the metal layer 326 is etched to pattern metal lines 328. The patterning of the metal lines 328 is done directly, and the conductive material of the extended vias 110 can be slightly etched during this process as well. This patterning process provides greater leeway with respect to tolerance restrictions. A planarization process (e.g., CMP) is employed to remove material to expose a conductive portion 318.

Referring to FIG. 13, a metal cut process is performed to remove the conductive portion 318 between the extended vias 110. The metal cut can be performed by patterning a mask (not shown) over metal lines 328 leaving the conductive portion 318 exposed. The conductive portion 318 can be removed by an etch process to form an opening 310 for the formation of a zero track skip in later steps. The etch process can be, e.g., a reactive ion etch (RIE) that stops on the dielectric material 112 to ensure all conductive materials are removed between the extended vias 110.

Referring to FIG. 14, a dielectric backfill is performed to fill the opening 310 (FIG. 13) with dielectric material to form a zero track skip 324. The dielectric backfill can be performed using any suitable process capable of narrow gap filling. For example, CVD, ALD or other deposition techniques can be employed to deposit dielectric materials to fill the opening 310. A planarization process, such as, e.g., CMP, can be performed to remove excess material from the free surface of the wafer 100 to form the zero track skip 324.

The zero track skip 324 acts as a break between portions of the metal line 328. Boundaries of the zero track skip 324 are defined by the extended vias 110, which extend from a different metal level 105 than the metal level 107 where the zero track skip 324 is located. In addition, the extended vias 110 are connected to the portions of the metal line 328 at interfaces 330 which extend along an entire sidewall of the extended vias 110. This improves resistance properties between the extended vias 110 and the portions of the metal line 328. Since the metal line 328 can be made thicker, resistance properties can be improved further by increasing contact surface area between the extended vias 110 and the portions of the metal line 328 by increasing a height of the metal line 328. Processing can continue with the formation of additional components, which can include additional dielectric layers and metal structures.

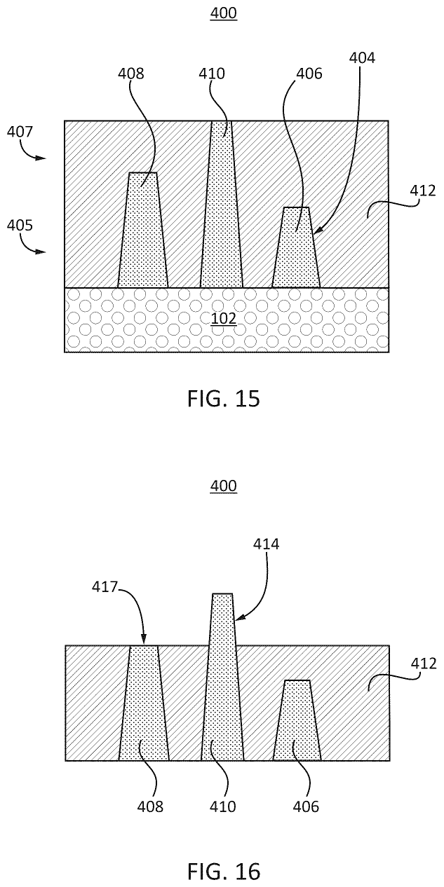

Referring to FIG. 15, in another embodiment, a metal layer 404 is formed on the substrate 102. A subtractive etch process or processes are carried out to form different metal structures from the metal layer 404. The metal layer 404 can include, e.g., Cu, Ru, Mo, Rh, W, Ir, and alloys or combinations of these and other conductive materials. In a particularly useful embodiment, the conductive fill includes Ru. The conductive fill can be formed using a deposition method, such as, e.g., CVD, PECVD, ALD or any other suitable deposition method. The conductive deposition can optionally be planarized, e.g., by CMP.

In an embodiment, metal lines 406 are formed by a first subtractive etch process by exposing portions of the metal layer 404 through an etch mask (not shown). Then, another etch mask (not shown) can be employed to etch vias 408 while blocking off other regions of a wafer 400. The vias 408 extend further than the metal lines 406 (e.g., are taller). Another etch mask (not shown) can be employed to etch extended via 410 while blocking off other regions of the wafer 400. The extended via 410 extend further than the metal lines 406 and the vias 408 (regular vias). Each of the features of the subtractive etch can be formed in any order since their formation is independently carried out relative to the others.

The vias 408 and metal lines 406 occupy a metal level, which can be referred to as a first metal level 405 (e.g., M1 metal). It should be understood metal level 405 can be anywhere in a stack of metal levels and is not limited to being positioned in a first metal level position. The extended via 410 extends beyond the first metal level 405 to at least partially traverse a second metal level 407.

A dielectric material 412 is formed on the wafer 400. The dielectric material 412 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric material 412 can be deposited using CVD, although other deposition methods can be employed. The dielectric material 412 can be planarized to expose a top surface of the extended via 410. The planarization process can include a CMP process.

Referring to FIG. 16, the dielectric material 412 is recessed to expose a top portion 414 of the extended vias 410. The recess process can include a wet or dry etch that recesses the dielectric material 412 until a top 417 of the via 408 is reached.

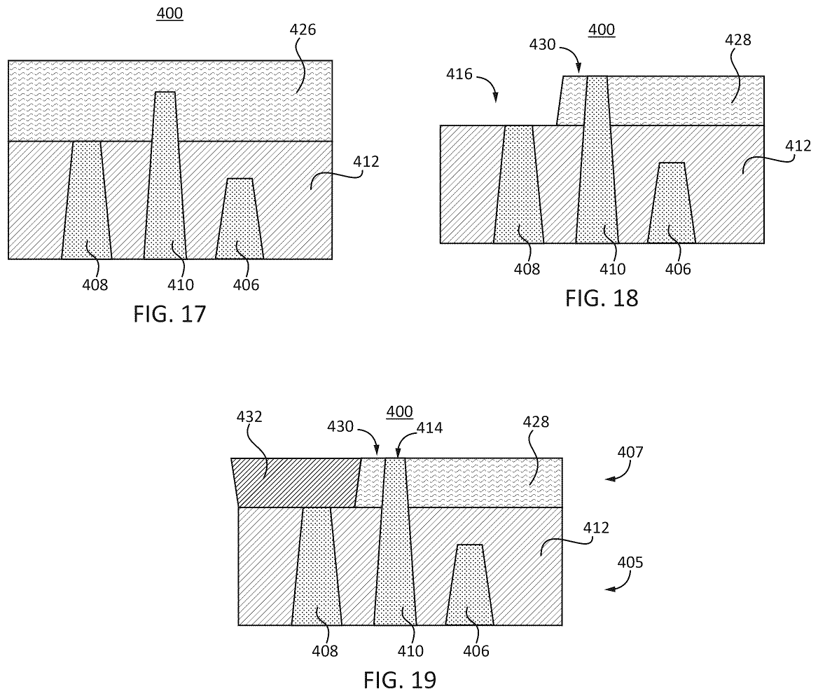

Referring to FIG. 17, a conductive deposition (blanket deposition) process can be performed to form a metal layer 426. The metal layer 426 can include materials, such as, e.g., Cu, Ru, Mo, Rh, W, Ir, and alloys or combinations of these and other conductive materials. In a particularly useful embodiment, the metal layer 426 includes Ru. The metal layer 426 can be formed using a deposition method, such as, e.g., CVD, PECVD, ALD or any other suitable deposition method. The metal layer 426 covers exposed portions of the extended via 410.

Referring to FIG. 18, a planarization process (e.g., CMP) or recess process is employed to remove material to expose the top portion of the extended via 410. The metal layer 426 is etched to pattern metal lines 428. The patterning of the metal lines 428 is done directly by, e.g., a reactive ion etch (RIE). Etching the metal layer 426 can include subtractively removing portions of the metal layer 426 to expose the dielectric material 412 and/or expose the regular vias 408 by creating open regions 416.

The metal line 428 can include a line portion 430 that extends beyond the extended via 410. The extended via 410 therefore includes portions (e.g., the line portion 430 and the metal line 428) on opposite sides of the extended via 410. In this instance, the top portion 414 of the extended via 410 is laterally encapsulated within the metal line 428. This greatly reduces contact resistance and improves reliability.

Referring to FIG. 19, a dielectric backfill is performed to fill the open regions 416 (FIG. 18) with dielectric material 432. The dielectric backfill can be performed using any suitable process. For example, CVD, ALD or other deposition techniques can be employed to deposit dielectric materials to fill the open regions 416 between and around metal lines 428. A planarization process, such as, e.g., CMP, can be performed to remove excess material from the free surface of the wafer 400.

The extended via 410 extends from a different metal level 405 to a metal level 407. The extended via 410 is embedded within the metal line 428 along an entire sidewall of the extended via 410. This improves resistance properties between the extended vias 410 and the metal line 428. Since the metal line 428 can be made thicker, resistance properties can be improved further by increasing contact surface area between the extended via 410 and the metal line 428 by increasing a height of the metal line 428. Processing can continue with the formation of additional components, which can include additional dielectric layers and metal structures.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a metal line having a longitudinal break therein to provide a first portion of the metal line and a second portion of the metal line;
a first extended via contacting an end of the first portion at a sidewall of the first extended via;
a second extended via being offset from the first extended via and contacting an end of the second portion at a sidewall of the second extended via;
the first extended via and the second extended via defining a space therebetween; and
a zero track skip disposed within the space.

2. The semiconductor device as recited in claim 1, wherein the metal line includes a thickness and the first extended via includes a height that extends through a portion of the thickness.

3. The semiconductor device as recited in claim 1, wherein the first extended via includes a height that traverses two metal levels.

4. The semiconductor device as recited in claim 1, wherein the second extended via includes a height that traverses two metal levels.

5. The semiconductor device as recited in claim 1, wherein the zero track skip is laterally bounded within the space between the first extended via and the second extended via.

6. The semiconductor device as recited in claim 1, wherein the first extended via and the second extended via have a same height.

7. A semiconductor device, comprising:
a pair of subtractively etched extended vias;
a dielectric layer disposed on the pair of subtractively etched extended vias, the pair of subtractively etched extended vias having top portions that extend above the dielectric layer;
a first metal line portion connected to a sidewall of one of the pair of subtractively etched extended vias;
a second metal line portion connected to a sidewall of another of the pair of subtractively etched extended vias;
the top portions defining a space therebetween; and
a zero track skip disposed within the space.

8. The semiconductor device as recited in claim 7, wherein the first metal line portion and the second metal line portion include a thickness and the pair of subtractively etched extended vias include a height that extends through a portion of the thickness.

9. The semiconductor device as recited in claim 7, wherein the pair of subtractively etched extended vias include a height that traverses two metal levels.

10. The semiconductor device as recited in claim 7, wherein the pair of subtractively etched extended vias include different heights.

11. The semiconductor device as recited in claim 7, wherein the zero track skip is laterally bounded within the space.

12. A semiconductor device, comprising:
a metal line having an end portion on a metal level; and
an extended via traversing a plurality of metal levels and being embedded in the end portion of the metal line on the metal level such that lateral portions of a top portion of the extended via are connected to the metal line.

13. The semiconductor device as recited in claim 12, wherein the metal line includes a thickness and the extended via includes a height that extends through the thickness in its entirety.

14. The semiconductor device as recited in claim 12, wherein the metal line includes a thickness and the extended via includes a height that extends through a portion of the thickness.

15. The semiconductor device as recited in claim 12, wherein the extended via includes a height that traverses two metal levels.

16. The semiconductor device as recited in claim 12, wherein the extended via includes portions of the metal line on opposite sides of the extended via.

17. A method for forming a semiconductor device, comprising:
subtractively etching a metal layer to form extended vias;
forming a first dielectric layer over the extended vias wherein the extended vias extend above the first dielectric layer;
forming a second dielectric layer on the first dielectric layer and over the extended vias to fill a space between top portions of the extended vias to form a zero track skip;
removing the second dielectric layer except the zero track skip; and
forming a metal line in contact with the extended vias, the metal line being separated by the zero track skip.

18. The method as recited in claim 17, wherein forming the second dielectric layer includes:
forming a width-dependent dielectric to cover the first dielectric layer without filling the space between top portions of the extended vias; and
forming a narrow gap fill dielectric to fill the space between top portions of the extended vias.

19. The method as recited in claim 17, wherein removing the second dielectric layer except the zero track skip includes forming a block mask over the zero track skip to prevent removal.

20. The method as recited in claim 17, wherein forming the metal line in contact with the extended vias includes forming the metal line with a thickness and the extended vias include a height that extends through a portion of the thickness.

21. The method as recited in claim 17, wherein the zero track skip and the second dielectric layer include different materials.

22. The method as recited in claim 17, wherein subtractively etching the metal layer includes subtractively etching the metal layer to form vias having at least two different heights.

23. A method for forming a semiconductor device, comprising:
subtractively etching a metal layer to form extended vias;
forming a first dielectric layer over the extended vias wherein the extended vias extend above the first dielectric layer;
blanket depositing a metal layer in contact with top portions of the extended vias;
forming metal lines having the top portions of the extended vias integrated within the metal lines;
performing a metal cut to cut metal lines by opening a space between the extended vias; and
forming a dielectric fill in the space between top portions of the extended vias to form a zero track skip.

24. The method as recited in claim 23, wherein forming the metal lines includes forming the metal lines with a thickness and the extended vias include a height that extends through a portion of the thickness.

25. The method as recited in claim 23, wherein subtractively etching the metal layer includes subtractively etching the metal layer to form vias having at least two different heights.
